(19) United States
(12) Patent Application Publication
(10) Pub. No.: US 2026/0125793 A1
(43) Pub. Date: May 7, 2026

(54) METHODS AND APPARATUS FOR FLOW DISTRIBUTION

(71) Applicant: ASM IP Holding B.V., Almere (NL)

(72) Inventors: Jereld Lee Winkler, Gilbert, AZ (US); Ankit Kimtee, Phoenix, AZ (US)

(21) Appl. No.: 19/375,448

(22) Filed: Oct. 31, 2025

Related U.S. Application Data
(60) Provisional application No. 63/716,445, filed on Nov. 5, 2024.

(51) Int. Cl. C23C 16/455; C23C 16/458; C23C 16/52

(52) U.S. Cl. CPC C23C 16/45519; C23C 16/45565; C23C 16/4585; C23C 16/52

(57) ABSTRACT

Various embodiments of the present technology may provide a spacer plate with a groove and an inlet aperture in fluid communication with the groove, a flow distribution ring disposed within the groove, wherein the flow distribution ring has a plurality of apertures, and a top ring disposed above the spacer plate and the flow distribution ring.

### CROSS-REFERENCE TO RELATED APPLICATIONS

This application is a nonprovisional of, and claims priority to and the benefit of, U.S. Provisional Patent Application No. 63/716,445, filed Nov. 5, 2024 and entitled “METHODS AND APPARATUS FOR FLOW DISTRIBUTION,” which is hereby incorporated by reference herein.

### FIELD OF INVENTION

The present disclosure generally relates to a method and apparatus for flow distribution. More particularly, the present disclosure relates to a flow distribution ring disposed within the spacer plate to provide a gas curtain around the susceptor.

### BACKGROUND OF THE TECHNOLOGY

Reaction chambers used in semiconductor manufacturing may contain spaces or volumes that need purging with an inert gas to prevent chemicals from depositing in those areas. Deposition of chemicals in these spaces may result in contamination of the reaction space and/or impair the functionality of parts within the reaction chamber.

### SUMMARY OF THE INVENTION

Various embodiments of the present technology may provide a spacer plate with a groove and an inlet aperture in fluid communication with the groove, a flow distribution ring disposed within the groove, wherein the flow distribution ring has a plurality of apertures, and a top ring disposed above the spacer plate and the flow distribution ring.

According to one aspect, an apparatus comprises: a spacer plate comprising: a groove; and an inlet aperture in fluid communication with the groove; a flow distribution ring disposed within the groove, wherein the flow distribution ring comprises a plurality of apertures; and a top ring disposed above the spacer plate and flow distribution ring.

In one embodiment, the plurality of apertures of the flow distribution ring are vertically oriented and in fluid communication with the groove.

In one embodiment, the groove is arranged within a top surface of the spacer plate.

In one embodiment, the groove is annular.

In one embodiment, the inlet aperture is arranged horizontally and coupled to a gas line.

In one embodiment, the top ring comprises a lip that extends radially inward.

In one embodiment, the lip is separated from the spacer place by a gap.

In one embodiment, the spacer plate comprises a lip that extends radially inward and overlaps with an outer edge of a support assembly.

In one embodiment, the spacer plate is formed from at least one of aluminum, nickel, stainless steel, and titanium; and the flow distribution ring is formed from at least one of aluminum, nickel, stainless steel, and titanium.

In one embodiment, the top ring is formed from at least one of ceramic and quartz.

According to another aspect, a reactor comprises: a lower chamber; a showerhead disposed above the lower chamber; a spacer plate disposed between the lower chamber and the showerhead, wherein the spacer plate comprises: an annular groove within a top surface of the spacer plate; an inlet aperture; and a first lip that extends radially inwards; a flow distribution ring disposed within the annular groove and comprising a plurality of apertures in fluid communication with the inlet aperture; a support assembly disposed within the reaction chamber, wherein the first lip of the spacer plate overlaps with an outer edge of susceptor support assembly; and a top ring coupled to the top surface of the spacer plate.

In one embodiment, the inlet aperture is arranged horizontally and coupled to an inlet port arranged on an outer surface of the reaction chamber.

In one embodiment, the top ring comprises a second lip that extends radially inward.

In one embodiment, the second lip of the top ring is separated from the spacer place by a first gap.

In one embodiment, the apparatus further comprises a seal disposed between the first lip of the spacer plate and the outer edge of the susceptor support assembly.

In one embodiment, the second lip of the top ring is separated from the susceptor support assembly by a second gap, wherein the second gap is arranged as an annular ring.

According to yet another aspect, a system comprises: a reactor comprising: a lower chamber; a showerhead disposed above the lower chamber; a spacer plate disposed between the lower chamber and the showerhead, wherein the spacer plate comprises: an annular groove within a top surface of the spacer plate; an inlet aperture; and a first lip that extends radially inwards; a flow distribution ring disposed within the annular groove and comprising a plurality of apertures in fluid communication with the inlet aperture; a susceptor support assembly disposed within the reaction chamber, wherein the first lip of the spacer plate overlaps with an outer edge of susceptor support assembly; and a top ring coupled to the top surface of the spacer plate; a gas line coupled to the inlet aperture, wherein the gas line comprises a first pipe section and a second pipe section, wherein the first and second pipe sections are in parallel with each other; and a pressure control device upstream from the first and second pipe sections.

In one embodiment, the system further comprises a first valve disposed in line with the first pipe section and a second valve disposed within the second pipe section.

In one embodiment, the gas line is further coupled to an inert gas source.

In one embodiment, the system further comprises a controller in communication with and configured to operate the first and second valves.

### BRIEF DESCRIPTION OF THE DRAWING FIGURES

A more complete understanding of the present technology may be derived by referring to the detailed description when considered in connection with the following illustrative figures. In the following figures, like reference numbers refer to similar elements and steps throughout the figures.

FIG. 1 representatively illustrates a system in accordance with embodiments of the present technology;

FIG. 2 is a cross-sectional view of a reactor in accordance with embodiments of the present technology;

FIG. 3A is a cross-sectional view of a reactor in accordance with embodiments of the present technology;

FIGS. 3B and 3C are cross-sectional views of a portion of a reactor in accordance with embodiments of the present technology;

FIG. 4 is top view of a portion of the reactor in accordance with embodiments of the present technology;

FIG. 5 is a top view of a spacer plate in accordance with embodiments of the present technology; and

FIG. 6 is a top view of a flow distribution ring in accordance with embodiments of the present technology.

### DETAILED DESCRIPTION OF EXEMPLARY EMBODIMENTS

The present technology may be described in terms of functional block components and various processing steps. Such functional blocks may be realized by any number of components configured to perform the specified functions and achieve the various results. For example, the present technology may employ various gas lines, valves, controllers, reaction chambers, vessels, and susceptors.

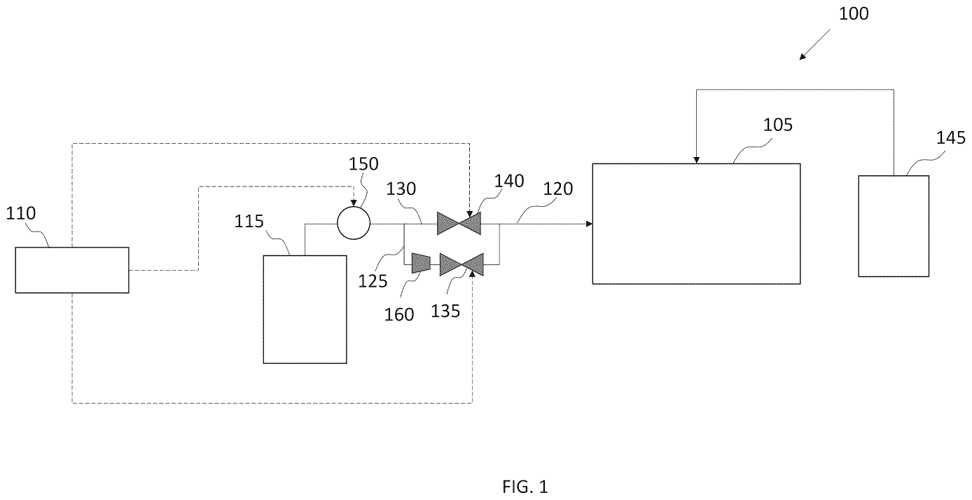

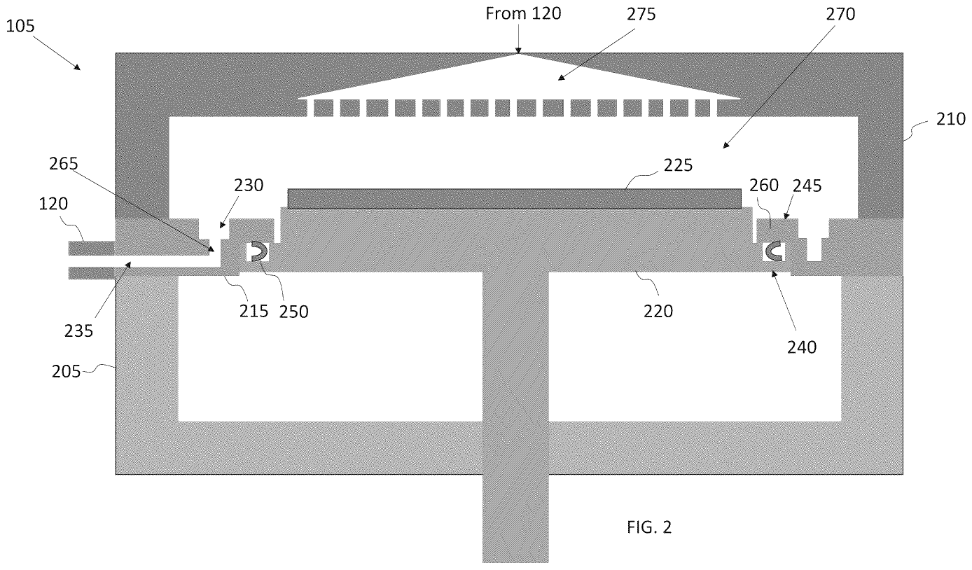

Referring to FIG. 1, an exemplary system 100 may comprise a reactor 105 configured to perform processing on an object to be processed, such as a substrate 225, e.g., a wafer (FIG. 2). For example, the reactor 105 may be configured to perform heating, deposition, etching, polishing, ion implantation, and/or other processing on the object to be processed. In some embodiments, the reactor 105 may be configured to perform a movement function, a vacuum sealing function, and an exhaust function. In some embodiments, the reactor 105 may perform an atomic layer deposition (ALD) process or a chemical vapor deposition (CVD) process.

In various embodiments, the system 100 may further comprise a vessel 145 configured to contain a chemical (i.e., a precursor). The vessel 145 may be configured to hold a solid or a liquid chemical, and may further be configured to transform the solid or liquid into a vapor. The vessel 145 may be coupled to the reactor 105. For example, the system 100 may further comprise various gas conduits and/or valves (not shown) to flow the vapor from the vessel 145 into the reactor 105.

In various embodiments, the system 100 may further comprise an inert gas source 115 configured to contain an inert gas, such as argon or the like. The inert gas source 115 may be fluidly coupled to the reactor 105 via any number of gas lines/conduits and/or valves. In an exemplary embodiment, the inert gas source 115 may be coupled to the reactor 105 via a gas line 120. The gas line 120 may comprise a first pipe section 125 and a second pipe section 130. The first pipe section 125 may be connected in parallel with the second pipe section 130. The first pipe section 125 may comprise a first valve 135 in line with the first pipe section 125. The first pipe section 125 may further comprise a restrictor 160 arranged upstream from the first valve 135 and configured to restrict flow through the first pipe section 125, the first valve 135 and the main gas line 120 that is downstream from the first pipe section 125. The first pipe section 125 may have a lower flow parameter than the flow parameter of the second pipe section 130 due to the restrictor 160.

Similarly, the second pipe section 130 may comprise a second valve 140 in line with the second pipe section 130. Each of the first and second valves 135, 140 may comprise a pneumatic valve, a mechanical valve, piezo electric, or the like. In various embodiments, the first and second valves 135, 140 may be operated according to a control signal transmitted from a controller 110. For example, the controller 110 may open/close each of the first and second valves 135, 140 independently from each other.

In various embodiments, the system 100 may further comprise a pressure controller 150 configured to monitor/sense the pressure in the main gas line 120 and/or control the pressure in the main gas line 120. The pressure controller 150 may be disposed in line with the main gas line 120 and upstream from the first and second pipe sections 125, 130. The pressure controller 150 may operate according to a desired set point. In some embodiments, the controller 110 may provide the set point to the pressure controller 150 via a signal.

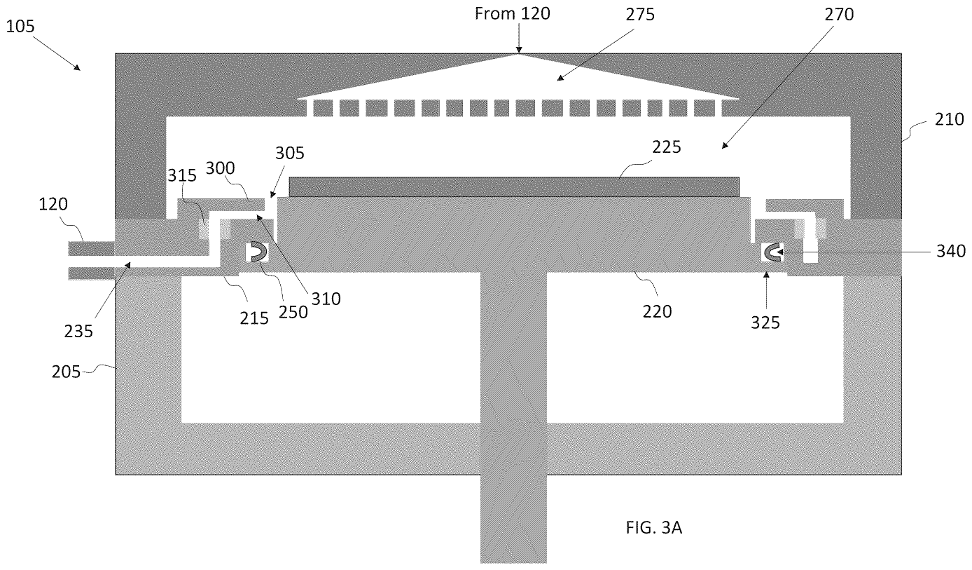

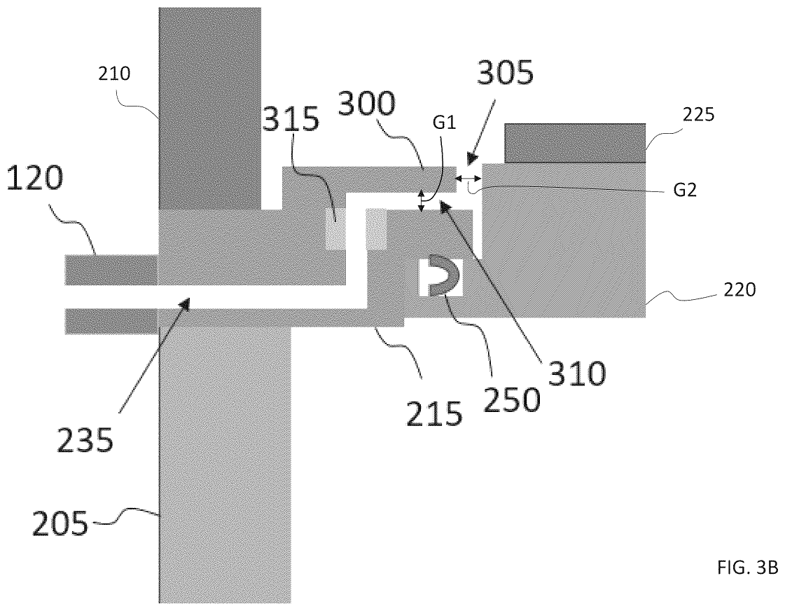

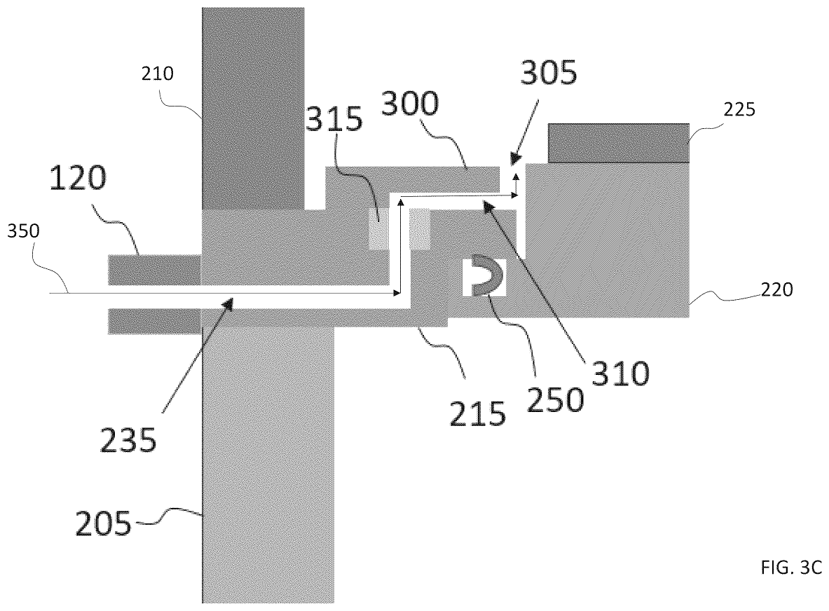

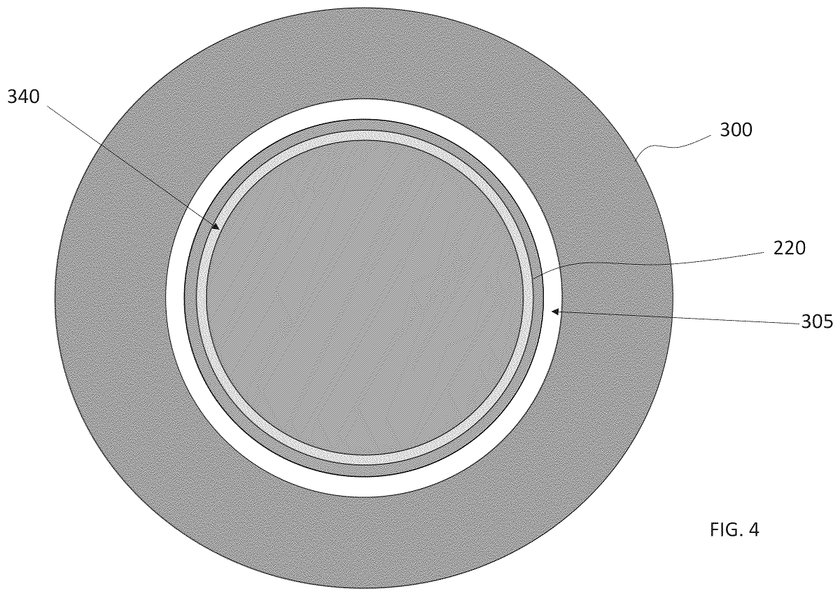

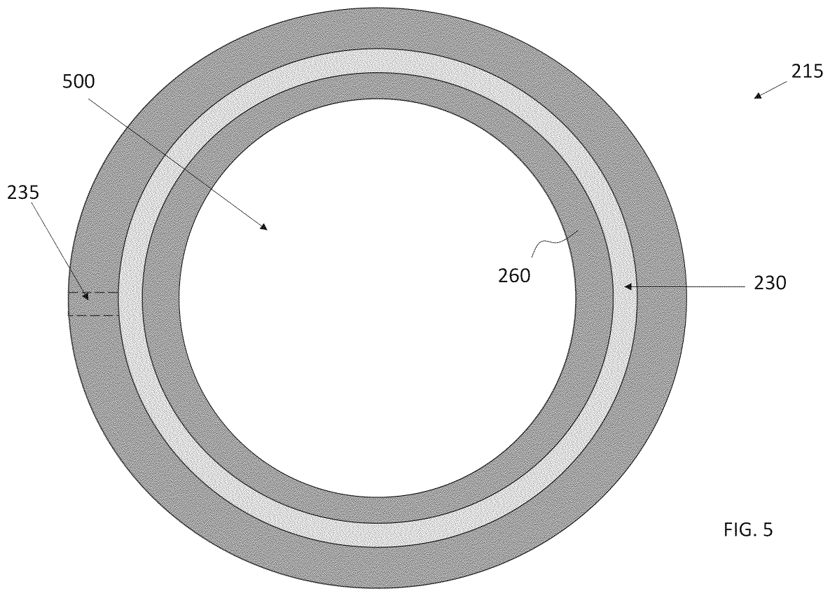

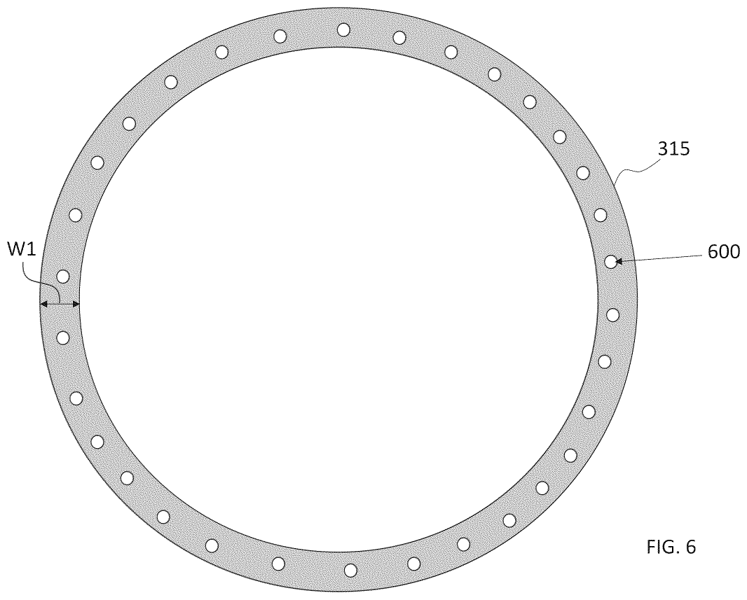

In various embodiments, and referring to FIGS. 2-6, the reactor 105 may comprise a lower chamber 205 and a showerhead 210 arranged above the lower chamber 205. The reactor 105 may further comprise a spacer plate 215 disposed between the lower chamber 205 and the showerhead 210. In various embodiments, the spacer plate 215 may form a ring shape having an opening 500 in the middle. The spacer plate 215 may further comprise a lip 260 that extends radially inward and forms the opening 500. In various embodiments, the spacer plate 215 may comprise a top, upwards facing surface 245. The top surface 245 may comprise a groove 230 having an annular shape. The groove 230 may be disposed radially outward from the lip 260. The spacer plate 215 may further comprise a channel 265 in fluid communication with the groove 230. The spacer plate 215 may be formed from aluminum, nickel alloy, titanium, stainless steel, or a combination thereof.

In various embodiments, the spacer plate may further comprise an inlet aperture 235. The inlet aperture 235 may be arranged horizontally and coupled to the gas line 120. The inlet aperture 235 may be in fluid communication with the channel 265.

In various embodiments, the reactor 105 may further comprise a flow distribution ring 315 configured to evenly distribute the inert gas around the substrate 225. The flow distribution ring 315 may comprise a plurality of apertures 600 that extends from a top surface of the flow distribution ring 315 to a bottom surface of the flow distribution ring 315. In various embodiments, the plurality of apertures 600 are vertically oriented. The plurality of aperture 600 may be in fluid communication with the channel 265. In an exemplary embodiment, the flow distribution ring 315 is sized and shaped to be disposed within the groove 230. In an exemplary embodiment, the flow distribution ring 315 may have a width W1 in a range of 10 mm to 15 mm. The flow distribution ring 315 may be formed from aluminum, nickel alloy, titanium, stainless steel, or a combination thereof.

In various embodiments, the reactor 105 may further comprise a top ring 300 configured to direct gas flow laterally across the spacer plate 215. The top ring 300 may be positioned above the spacer plate 215 and extend radially inward toward the susceptor support assembly 220. The top ring 300 may be attached to the spacer plate 215, for example with a screw, or the like. In various embodiments, the top ring 300 may be arranged to allow gas to flow from the channel 265 and into a first gap 310 formed between the top ring 300 and the spacer plate 215. The first gap 310 may have a height G1 in the range of 1 mm to 5 mm. A second gap 305 may be formed between an inner edge of the top ring 300 and the susceptor support assembly 200. The second gap 305 may have a width in the range of 2 mm to 5 mm. The first gap 310 may be in fluid communication with the second gap 305 to allow gas to flow into the reaction space 270.

In various embodiments, the system 100 may further comprise a susceptor support assembly 220 disposed within the reactor 105. The susceptor support assembly 220 may comprise surface for supporting the substrate 225 and a heater (not shown) for heating the substrate 225. The heater may be embedded within the susceptor support assembly 220. For loading/unloading of the substrate 225, the susceptor support assembly 220 may be configured to be vertically movable (up and down) by being connected to a driving unit (not shown). In an exemplary embodiment, the susceptor support assembly 220 may further comprise a protrusion 325 along an outer edge of the susceptor support assembly 220. The protrusion 325 may comprise an annular channel 340 having a seal 250 disposed within the channel 340. The seal 250 may be a metal seal, such as an e-seal, or the like.

In various embodiments, the showerhead 210 may be arranged adjacent to the lower chamber 205. For example, the showerhead 210 may be disposed on the sidewalls of the lower chamber 205. In some embodiments, the showerhead 210 may be fastened to the sidewalls, however, in other cases, the showerhead 210 may merely rest on the sidewalls of the lower chamber 205. In various embodiments, the showerhead 210 together with the lower chamber 205 sidewalls form an enclosed space, including a reaction space 270.

In various embodiments, the showerhead 210 may comprise an inlet plenum 275 configured to receive gas from the inert gas source 115. For example, the inlet plenum 275 may be coupled to the inert gas source 115 via the main gas line 120. The inlet plenum 275 may be in fluid communication with the reaction space 270 via a plurality of through holes in the showerhead 210.

In operation, and referring to FIGS. 1-6, the system 100 may provide a flow pattern 350 to prevent deposition of chemistry in undesired areas of the reactor 105. For example, gas may flow from the inert gas source 115, through the main gas line 120, and into the reactor 105. In particular, the gas may flow into the inlet aperture 235 of the spacer plate 215, through the channel 265 and then through the plurality of apertures 600 in the flow distribution ring 315. The gas may exit the plurality of apertures 600 and continue to flow through the first and second gaps G1, G2, and into the reaction space 270. The flow pattern 350 may provide a continuous gas curtain around the susceptor support assembly 220 and the substrate 225. The flow pattern 350 may prevent deposition in the cavity between the spacer plate 215 and the susceptor support assembly 220. The flow pattern 350 may also prevent deposition on the seal 250 and/or within the channel 340.

In operation, the controller 110 may control operation of the first and second valves 135, 140 to provide a desired flow rate into the reactor 105. For example, and with respect to an ALD (atomic layer deposition) process, during a pulse (dose) step, the controller 110 may open the second valve 140 and close the first valve 135, thus allowing the gas to flow through the second pipe section 130, which has a higher flow rate than the first pipe section 125. In addition, during a purge step, the controller 110 may close the second valve 140 and open the first valve 135, thus allowing the gas to flow through the first pipe section 125, which has a lower flow rate than the second pipe section 130. Providing a low flow during the purge step may prevent turbulence at the edge of the substrate 225. Providing a low flow during the purge step may also allow the precursor to be exhausted from the reaction space 270. Providing a high flow during the pulse step provides additional inert gas flow at perimeter of the susceptor (outside the perimeter of the wafer and reaction space 270) and creates a higher pressure zone which acts to lower outflow from the reaction space 270. The higher pressure zone created by the inert gas flow may reduce precursor outflow, which may increase precursor utilization rate and reduce precursor consumption/waste. It should be noted that alternative high and low flow may be utilized in other processes or in the ALD process.

In the foregoing description, the technology has been described with reference to specific exemplary embodiments. The particular implementations shown and described are illustrative of the technology and its best mode and are not intended to otherwise limit the scope of the present technology in any way. Indeed, for the sake of brevity, conventional manufacturing, connection, preparation, and other functional aspects of the method and system may not be described in detail. Furthermore, the connecting lines shown in the various figures are intended to represent exemplary functional relationships and/or steps between the various elements. Many alternative or additional functional relationships or physical connections may be present in a practical system.

The technology has been described with reference to specific exemplary embodiments. Various modifications and changes, however, may be made without departing from the scope of the present technology. The description and figures are to be regarded in an illustrative manner, rather than a restrictive one and all such modifications are intended to be included within the scope of the present technology. Accordingly, the scope of the technology should be determined by the generic embodiments described and their legal equivalents rather than by merely the specific examples described above. For example, the steps recited in any method or process embodiment may be executed in any order, unless otherwise expressly specified, and are not limited to the explicit order presented in the specific examples. Additionally, the components and/or elements recited in any apparatus embodiment may be assembled or otherwise operationally configured in a variety of permutations to produce substantially the same result as the present technology and are accordingly not limited to the specific configuration recited in the specific examples.

Benefits, other advantages and solutions to problems have been described above with regard to particular embodiments. Any benefit, advantage, solution to problems or any element that may cause any particular benefit, advantage or solution to occur or to become more pronounced, however, is not to be construed as a critical, required or essential feature or component.

The terms “comprises”, “comprising”, or any variation thereof, are intended to reference a non-exclusive inclusion, such that a process, method, article, composition or apparatus that comprises a list of elements does not include only those elements recited, but may also include other elements not expressly listed or inherent to such process, method, article, composition or apparatus. Other combinations and/or modifications of the above-described structures, arrangements, applications, proportions, elements, materials or components used in the practice of the present technology, in addition to those not specifically recited, may be varied or otherwise particularly adapted to specific environments, manufacturing specifications, design parameters or other operating requirements without departing from the general principles of the same.

The present technology has been described above with reference to an exemplary embodiment. However, changes and modifications may be made to the exemplary embodiment without departing from the scope of the present technology. These and other changes or modifications are intended to be included within the scope of the present technology, as expressed in the following claims.

What is claimed is:

1. An apparatus, comprising:
a spacer plate comprising:
a groove; and
an inlet aperture in fluid communication with the groove;
a flow distribution ring disposed within the groove, wherein the flow distribution ring comprises a plurality of apertures; and
a top ring disposed above the spacer plate and flow distribution ring.

2. The apparatus according to claim 1, wherein the plurality of apertures of the flow distribution ring are vertically oriented and in fluid communication with the groove.

3. The apparatus according to claim 1, wherein the groove is arranged within a top surface of the spacer plate.

4. The apparatus according to claim 1, wherein the groove is annular.

5. The apparatus according to claim 1, wherein the inlet aperture is arranged horizontally and coupled to a gas line.

6. The apparatus according to claim 1, wherein the top ring comprises a lip that extends radially inward.

7. The apparatus according to claim 6, wherein the lip is separated from the spacer place by a gap.

8. The apparatus according to claim 1, wherein the spacer plate comprises a lip that extends radially inward and overlaps with an outer edge of a support assembly.

9. The apparatus according to claim 1, wherein:
the spacer plate is formed from at least one of aluminum, nickel, stainless steel, and titanium; and
the flow distribution ring is formed from at least one of aluminum, nickel, stainless steel, and titanium.

10. The apparatus according to claim 1, wherein the top ring is formed from at least one of ceramic and quartz.

11. A reactor, comprising:
a lower chamber;
a showerhead disposed above the lower chamber;
a spacer plate disposed between the lower chamber and the showerhead, wherein the spacer plate comprises:
an annular groove within a top surface of the spacer plate;
an inlet aperture; and
a first lip that extends radially inwards;
a flow distribution ring disposed within the annular groove and comprising a plurality of apertures in fluid communication with the inlet aperture;
a support assembly disposed within the reaction chamber, wherein the first lip of the spacer plate overlaps with an outer edge of susceptor support assembly; and
a top ring coupled to the top surface of the spacer plate.

12. The reactor according to claim 11, wherein the inlet aperture is arranged horizontally and coupled to an inlet port arranged on an outer surface of the reaction chamber.

13. The reactor according to claim 11, wherein the top ring comprises a second lip that extends radially inward.

14. The reactor according to claim 11, wherein the second lip of the top ring is separated from the spacer place by a first gap.

15. The reactor according to claim 11, further comprising a seal disposed between the first lip of the spacer plate and the outer edge of the susceptor support assembly.

16. The reactor according to claim 11, wherein the second lip of the top ring is separated from the susceptor support assembly by a second gap, wherein the second gap is arranged as an annular ring.

17. A system, comprising:
a reactor comprising:
a lower chamber;
a showerhead disposed above the lower chamber;
a spacer plate disposed between the lower chamber and the showerhead, wherein the spacer plate comprises:
an annular groove within a top surface of the spacer plate;
an inlet aperture; and
a first lip that extends radially inwards;
a flow distribution ring disposed within the annular groove and comprising a plurality of apertures in fluid communication with the inlet aperture;
a susceptor support assembly disposed within the reaction chamber, wherein the first lip of the spacer plate overlaps with an outer edge of susceptor support assembly; and
a top ring coupled to the top surface of the spacer plate;
a gas line coupled to the inlet aperture, wherein the gas line comprises a first pipe section and a second pipe section, wherein the first and second pipe sections are in parallel with each other; and
a pressure control device upstream from the first and second pipe sections.

18. The system according to claim 17, further comprising a first valve disposed in line with the first pipe section and a second valve disposed within the second pipe section.

19. The system according to claim 17, wherein the gas line is further coupled to an inert gas source.

20. The system according to claim 17, further comprising a controller in communication with and configured to operate the first and second valves.
